(19) United States
(12) Patent Application Publication
(10) Pub. No.: US 2024/0154029 A1
(43) Pub. Date: May 9, 2024

(54) METHODS AND SYSTEMS OF OPERATING A PNP BI-DIRECTIONAL DOUBLE-BASE BIPOLAR JUNCTION TRANSISTOR

(71) Applicant: IDEAL POWER INC., Austin, TX (US)

(72) Inventors: R. Daniel BRDAR, Driftwood, TX (US); Jiankang BU, Austin, TX (US); Ruiyang YU, Austin, TX (US); Mudit KHANNA, Austin, TX (US)

(73) Assignee: IDEAL POWER INC., Austin, TX (US)

(21) Appl. No.: 18/483,939

(22) Filed: Oct. 10, 2023

Related U.S. Application Data
(60) Provisional application No. 63/382,924, filed on Nov. 9, 2022.

(51) Int. Cl. H01L 29/735; H01L 29/06; H01L 29/08; H01L 29/66

(52) U.S. Cl. CPC H01L 29/735; H01L 29/0611; H01L 29/0821; H01L 29/6625

(57) ABSTRACT

Operating a PNP double-sided double-base bipolar junction transistor (DSDB BJT). One example is a method of operating a DSDB-BJT, the method comprising: conducting a first load current from an upper terminal of the power module to an upper base of the transistor, through the transistor, and from a lower base to a lower terminal of the power module; and then responsive assertion of a first interrupt signal interrupting the first load current from the lower base to the lower terminal by opening a lower-main FET and commutating a first shutoff current through a lower collector-emitter of the transistor to the lower terminal; and blocking current from the upper terminal to the lower terminal by the transistor.

### CROSS-REFERENCE TO RELATED APPLICATIONS

This application claims the benefit of U.S. Provisional App. 63/382,924 filed Nov. 9, 2022 and titled “Methods and Systems of Operating a PNP Bi-Directional Double-Base Bipolar Junction Transistor (B-TRAN).” The provisional application is incorporated by reference herein as if reproduced in full below.

### BACKGROUND

A double-sided double-base (DSDB) bipolar junction transistor (BJT) (hereafter DSDB-BJT) is a junction transistor constructed with a base and collector-emitter on a first side of the bulk region, and a distinct and separate base and collector-emitter on a second side of the bulk region opposite the first side. When properly configured by an external driver, electrical current may selectively flow through the collector-emitters of a DSDB-BJT in either direction, and thus DSDB-BJT devices are considered bi-directional devices. Based on the bi-directionality, whether a collector-emitter is considered a collector or an emitter depends on the polarity of the applied external voltage and thus the direction of current flow through the DSDB-BJT.

DSDB-BJT devices may be constructed as NPN devices that are normally off or normally non-conductive from the upper collect-emitter to the lower collector-emitter (and vice versa). DSDB-BJT devices may also be constructed as PNP devices that are normally on or normally conductive from the upper collect-emitter to the lower collector-emitter (and vice versa).

### SUMMARY

At least one example is a method of operating a power module having a bi-directional double-base bipolar junction transistor, the method comprising: conducting a first load current from an upper terminal of the power module to an upper base of the transistor, through the transistor, and from a lower base to a lower terminal of the power module; and then responsive assertion of a first interrupt signal, interrupting the first load current from the lower base to the lower terminal by opening a lower-main FET and commutating a first shutoff current through a lower collector-emitter of the transistor to the lower terminal; and blocking current from the upper terminal to the lower terminal by the transistor.

In the example method, during the conducting, the method further comprises injecting charge carriers into an upper collector-emitter, and the method may further comprise, responsive to the assertion of the first interrupt signal, ceasing the injection of charge carriers into the upper collector-emitter. Ceasing injection of charge carriers may further comprise ceasing injection of charge carriers a non-zero predetermined time before the interrupting the first load current by opening the lower-main FET.

In the example method: interrupting the first load current may further comprise interrupting the first load current with the lower-main FET having a breakdown voltage of 100 Volts or less; and blocking current may further comprise blocking at an applied voltage across the upper terminal and the lower terminal of 600 Volts or greater.

In the example method, commutating the first shutoff current may further comprise coupling the lower collector-emitter to the lower terminal. Coupling the lower collector-emitter to the lower terminal may further comprise coupling the lower collector-emitter to the lower terminal by way of a voltage source or a current source.

The example method may further comprise, after blocking current from the upper terminal to the lower terminal: conducting a second load current from the lower terminal of the power module to the lower base, through the transistor, and from the upper base to the upper terminal; and then responsive to assertion of a second interrupt signal, interrupting the second load current from the upper base to the upper terminal by opening an upper-main FET and commutating a second shutoff current through an upper collector-emitter to the upper terminal; and blocking current from the lower terminal to the upper terminal by the transistor. Interrupting the second load current may further comprise interrupting the second load current with the upper-main FET having a breakdown voltage of 100 Volts or less, blocking current from the lower terminal to the upper terminal may further comprise blocking at an applied voltage across the lower terminal and the upper terminal of 600 Volts or greater.

Yet another example is a switch assembly comprising: an upper terminal, a lower terminal, and an upper-control input; a transistor defining an upper base, an upper collector-emitter, a lower base, and a lower collector-emitter; an upper-main FET defining a first lead coupled to the upper terminal, a second lead coupled to the upper base, and a gate; a lower-main FET defining a first lead coupled to the lower base, a second lead coupled to the lower terminal, and a gate; and a controller coupled to the upper-control input, the gate of the upper-main FET, and the gate of the lower-main FET, and for a first applied voltage across the upper terminal and lower terminal. The controller may be configured to: assert the gate of the upper-main FET to make the upper-main FET conductive, arrange the transistor for conduction from the upper base to the lower base, and assert the gate of the lower-main FET to make the lower-main FET conductive such that a first load current flows from the upper terminal to the lower terminal; sense de-assertion of the upper-control input; and responsive to de-assertion of the upper-control input de-assert the gate of the lower-main FET to interrupt the first load current from the lower base.

In the example switch assembly, a breakdown voltage of the transistor may be 600 Volts or greater, and the breakdown voltage of the lower-main FET may be 100 Volts or less.

In the example switch assembly, a breakdown voltage of the transistor may be about 1200 Volts, and the breakdown voltage of the lower-main FET may be 80 Volts or less.

The example switch assembly may further comprise: an upper-CE source and an upper-CE FET, the upper-CE source arranged to selectively inject charge carriers into the upper collector-emitter through the upper-CE FET; and wherein when the controller arranges the transistor for conduction from the upper base to the lower base, the controller is further configured to make the upper-CE FET conductive to inject charge carriers into the upper collector-emitter; and wherein when the controller senses de-assertion of the upper-control input, the controller is further configured to make the upper-CE FET non-conductive to cease injection of charge carriers into the upper collector-emitter. When the controller makes the upper-CE FET non-conductive, the controller may be configured to make the upper-CE FET non-conductive a predetermined period of time that is non-zero before de-asserting the gate of the lower-main FET. When the controller senses de-assertion of the upper-control input, the controller may be further configured to electrically float the upper collector-emitter.

The example switch assembly may further comprise: a lower-CE FET defining a first lead coupled to the lower collector-emitter, a second lead coupled to the lower terminal, and a gate coupled to the controller; wherein when the controller senses de-assertion of the upper-control input, the controller is further configured to assert the gate of the lower-CE FET to commutate a shutoff current to the lower terminal. The switch assembly may further comprise: a lower-CE source arranged to selectively extract charge carriers from the lower collector-emitter through the lower-CE FET; wherein when the controller senses de-assertion of the upper-control input, the controller may be further configured to make the lower-CE FET conductive to extract charge carriers from the lower collector-emitter.

The example switch assembly may further comprise: a lower-control input coupled to the controller; and wherein for a second applied voltage across the upper terminal and lower terminal, the second applied voltage having a polarity opposite the first applied voltage, the controller may be further configured to: assert the gate of the lower-main FET to make the lower-main FET conductive, arrange the transistor for conduction from the lower base to the upper base, and assert the gate of the upper-main FET to make the upper-main FET conductive such that a second load current flows from the lower terminal to the upper terminal; sense de-assertion of the lower-control input; and responsive to de-assertion of the lower-control input, de-assert the gate of the upper-main FET to interrupt the second load current from the upper base. The example switch assembly may further comprise: a lower-CE source and a lower-CE FET, the lower-CE source arranged to selectively inject charge carriers into the lower collector-emitter through the lower-CE FET; and wherein when the controller arranges the transistor for conduction from the lower base to the upper base, the controller may be further configured to make the lower-CE FET conductive to inject charge carriers into the lower collector-emitter; and wherein when the controller senses de-assertion of the lower-control input, the controller may be further configured to make the lower-CE FET non-conductive to cease injection of charge carriers into the lower collector-emitter.

Another example is a second example method of operating a bi-directional double-base bipolar junction transistor, the method comprising: making the transistor conductive from an upper base to a lower base by supplying current to an upper collector-emitter of the transistor and electrically floating a lower collector-emitter of the transistor; and then making the transistor non-conductive by electrically floating the upper collector-emitter, electrically floating the lower base, and conducting a shutoff current through the lower collector-emitter of the transistor.

In the second example method, electrically floating the lower base may further comprises making non-conductive a lower-main electrically-controlled switch having a first lead coupled to the lower base.

In the second example method, making the transistor conductive may further comprise: closing an upper-main electrically-controlled switch coupled between an upper terminal and the upper base; and closing a lower-main electrically-controlled switch coupled between a lower terminal and the lower base. Making the transistor non-conductive may further comprise: opening the upper-main electrically-controlled switch;

conducting the shutoff current to the upper base through a diode associated with the upper-main electrically-controlled switch; and commutating the shutoff current from the lower base to the lower collector-emitter by opening the lower-main electrically-controlled switch.

### BRIEF DESCRIPTION OF THE DRAWINGS

For a detailed description of example embodiments, reference will now be made to the accompanying drawings in which:

FIG. 1 shows a partial block diagram, partial electrical schematic, of a power module using an NPN DSDB-BJT;

FIG. 2 shows a partial block diagram, partial electrical schematic, of a power module using a PNP DSDB-BJT;

FIG. 3 shows a partial block diagram, partial electrical schematic, of a power module using a PNP DSDB-BJT in accordance with at least some embodiments;

FIG. 4 shows a cross-sectional elevation view of a PNP DSDB-BJT in accordance with at least some embodiments;

FIGS. 5A-5G show an NPN DSDB-BJT in shorthand form, with example external electrical connections, to illustrate several operational states of the NPN DSDB-BJT, in accordance with at least some embodiments;

FIG. 6 shows a partial block diagram, partial electrical schematic, of a switch assembly in accordance with at least some embodiments;

FIG. 7 shows a partial electrical schematic of an example switch assembly, in accordance with at least some embodiments;

FIG. 8 shows a method in accordance with at least some embodiments; and

FIG. 9 shows a method in accordance with at least some embodiments.

### DEFINITIONS

Various terms are used to refer to particular system components. Different companies may refer to a component by different names—this document does not intend to distinguish between components that differ in name but not function. In the following discussion and in the claims, the terms “including” and “comprising” are used in an open-ended fashion, and thus should be interpreted to mean “including, but not limited to . . . .” Also, the term “couple” or “couples” is intended to mean either an indirect or direct connection. Thus, if a first device couples to a second device, that connection may be through a direct connection or through an indirect connection via other devices and connections.

“About” in reference to a recited parameter shall mean the recited parameter plus or minus ten percent (+/−10%) of the recited parameter.

“Assert” shall mean creating or maintaining a first predetermined state of a Boolean signal. Boolean signals may be asserted high or with a higher voltage, and Boolean signals may be asserted low or with a lower voltage, at the discretion of the circuit designer. Similarly, “de-assert” shall mean creating or maintaining a second predetermined state of the Boolean, opposite the asserted state.

“FET” shall mean a field effect transistor, such as a junction-gate FET (JFET) or metal-oxide-silicon FET (MOSFET).

“Closing” in reference to an electrically-controlled switch (e.g., a FET) shall mean making the electrically-controlled switch conductive. For example, closing a FET used as an electrically-controlled switch may mean driving the FET to the fully conductive state.

“Opening” in reference to an electrically-controlled switch (e.g., a FET) shall mean making the electrically-controlled switch non-conductive.

“Double-sided double-base bipolar junction transistor” shall mean a junction transistor having a base and a collector-emitter on a first face or first side of a bulk region, and having a base and a collector-emitter on a second face or second side of the bulk region. The base and the collector-emitter on the first side are distinct from the base and the collector-emitter on the second side.

“Collector-emitter region” of a PNP bidirectional device shall mean a region of P-type doping that forms a junction with a bulk substrate and/or base region of N-type doping. Portions of the collector-emitter region with varying carrier concentrations (e.g., P transitioning to P±) shall not be considered a different doping type.

“Collector-emitter” shall mean an electrical pin or terminal coupled directly to a collector-emitter region. The presence of intervening wire bonds and bond pads shall not obviate a collector-emitter as being directly coupled to the collector-emitter region.

“Upper collector-emitter” shall mean a collector-emitter of a double-sided double-base bipolar junction transistor on a first side of a bulk region of the transistor, and shall not be read to imply a location of the collector-emitter with respect to gravity.

“Lower collector-emitter” shall mean a collector-emitter of a double-sided double-base bipolar junction transistor on a second side of a bulk region of the transistor opposite a first side, and shall not be read to imply a location of the collector-emitter with respect to gravity.

“Base region” of a PNP bidirectional device shall mean a region of N-type doping that is contiguous with a bulk substrate of N-type doping. Portions of the base region with varying carrier concentrations (e.g., N transitioning to N⁺) shall not be considered a different doping type.

“Base” shall mean an electrical pin or terminal coupled directly to a base region. The presence of intervening wire bonds and bond pads shall not obviate a base being directly coupled to the base region.

“Upper base” shall mean a base of a double-sided double-base bipolar junction transistor on a first side of the transistor, and shall not be read to imply a location of the base with respect to gravity.

“Lower base” shall mean a base of a double-sided double-base bipolar junction transistor on a second side of the transistor opposite a first side, and shall not be read to imply a location of the base with respect to gravity.

The terms “input” and “output” when used as nouns refer to connections (e.g., electrical, software), and shall not be read as verbs requiring action. For example, a timer circuit may define a clock output. The example timer circuit may create or drive a clock signal on the clock output. In systems implemented directly in hardware (e.g., on a semiconductor substrate), these “inputs” and “outputs” define electrical connections. In systems implemented in software, these “inputs” and “outputs” define parameters read by or written by, respectively, the instructions implementing the function.

“Controller” shall mean, alone or in combination, individual circuit components, an application specific integrated circuit (ASIC), a microcontroller with controlling software, a reduced-instruction-set computing (RISC) with controlling software, a digital signal processor (DSP), a processor with controlling software, a programmable logic device (PLD), a field programmable gate array (FPGA), or a programmable system-on-a-chip (PSOC), configured to read inputs and drive outputs responsive to the inputs.

### DETAILED DESCRIPTION

The following discussion is directed to various embodiments of the invention. Although one or more of these embodiments may be preferred, the embodiments disclosed should not be interpreted, or otherwise used, as limiting the scope of the disclosure, including the claims. In addition, one skilled in the art will understand that the following description has broad application, and the discussion of any embodiment is meant only to be exemplary of that embodiment, and not intended to intimate that the scope of the disclosure, including the claims, is limited to that embodiment.

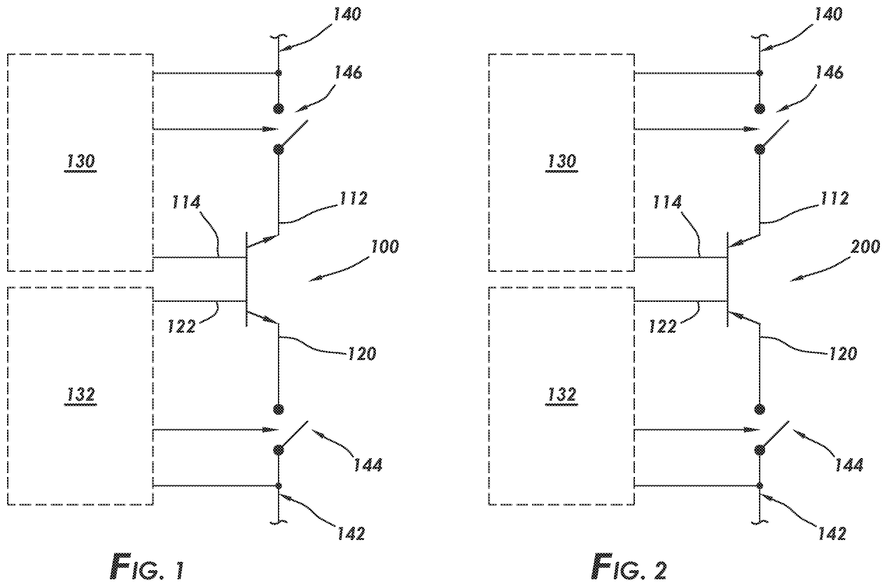

Various examples are directed to methods and systems of operating a PNP double-sided double-base (DSDB) bipolar junction transistor (BJT), hereafter just DSDB-BJT. The specification first turns to related-art methods and systems of operating an NPN DSDB-BJT. Co-pending and commonly assigned U.S. application Ser. No. 17/537,726 filed Nov. 30, 2021, describes a power module using a DSDB-BJT device in which the main current flow through the DSDB-BJT device is from the upper collector-emitter to the lower collector-emitter, and vice versa. FIG. 1 shows a partial block diagram, partial electrical schematic, of a power module using a DSDB-BJT of NPN construction. In particular, visible in FIG. 1 is a DSDB-BJT 100 defining an upper collector-emitter 112, an upper base 114, a lower collector-emitter 120, and a lower base 122. As shown by the circuit symbol, the DSDB-BJT 100 is of NPN construction. A DSDB-BJT of NPN construction is a normally off or normally non-conductive device. In order to arrange the DSDB-BJT 100 for selective conduction in either direction, the DSDB-BJT 100 is associated with the driver circuit. In particular, the upper collector-emitter 112 and the upper base 114 may be associated with an upper driver 130, and the lower collector-emitter 120 and lower base may be associated with a lower driver 132. The upper driver 130 is designed and constructed to selectively: float the upper base 114; short the upper base 114 to the upper terminal 140; and inject charge carriers into the upper base 114 to lower the V_{CEON} of the DSDB-BJT 100 during periods of conduction from the upper terminal 140 to the lower terminal 142. Similarly, the lower driver 132 is designed and constructed to selectively: float the lower base 122; short the lower base 122 to the lower terminal 142; and inject charge carriers into the lower base 122 to lower the V_{CEON} of the DSDB-BJT 100 during periods of conduction from the lower terminal 142 to the upper terminal 140.

In the example of FIG. 1 the DSDB-BJT 100 of NPN construction is arranged for cascode operation with current flowing in either direction. In particular, the DSDB-BJT 100 is associated with a lower electrically-controlled switch (hereafter just switch 144) coupled between the lower collector-emitter 120 and the lower terminal 142. The switch 144 is selected and implemented to interrupt the load current from the upper terminal 140, through the collector-emitters 112 and 120, and to the lower terminal 142 when the externally applied voltage is more positive on the upper terminal 140. Relatedly, the DSDB-BJT 100 is associated with an upper electrically-controlled switch (hereafter just switch 146) coupled between the upper terminal 140 and the upper collector-emitter 112. The switch 146 is selected and implemented to interrupt the load current from the lower terminal 142, through the collector-emitters 120 and 112, and to the upper terminal 140 when the externally applied voltage is more positive on the lower terminal 142. Thus, in the arrangement of FIG. 1 using a DSDB-BJT 100, the load current flows through collector-emitters 112 and 120 as controlled by voltages and current applied to the upper base 114 and lower base 122.

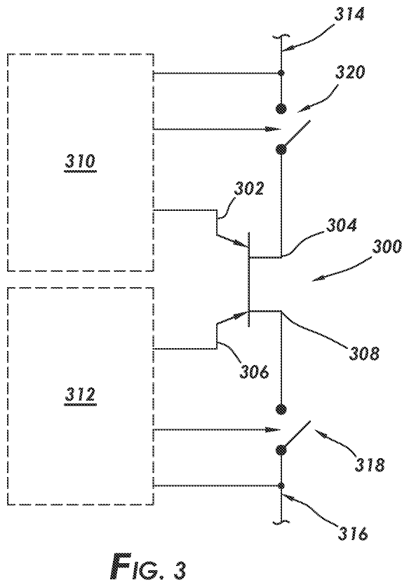

The co-pending and commonly assigned application noted above indicates that a similar power module could be implemented using a DSDB-BJT of PNP construction. FIG. 2 shows a partial block diagram, partial electrical schematic, of a power module using a DSDB-BJT of PNP construction. In particular, visible in FIG. 2 is a DSDB-BJT 200. As shown by the circuit symbol, the DSDB-BJT 200 is of PNP construction. The DSDB-BJT 200 defines the upper collector-emitter 112, the upper base 114, the lower collector-emitter 120, and the lower base 122. As a PNP transistor is a normally on or normally conductive device, the upper driver 130 and lower driver 132 would be designed and constructed to arrange the DSDB-BJT 200 for non-conduction during periods when the power module is blocking current. Again as before, even in the case of the power module implementing a DSDB-BJT 200 of PNP construction, the DSDB-BJT may also be arranged for cascode operation in which current interruption is implemented by the switches 144 or 146 depending on the direction of current flow.

Referring simultaneously to FIGS. 1 and 2, the inventors of the current specification believe that one of ordinary skill in the art, tasked with the implementing a power module using a DSDB-BJT of PNP construction, would implement the design of FIG. 2 in which the collector-emitters are used as the primary load current path through the DSDB-BJT device. Stated otherwise, one of ordinary skill in the art would implement a design in which the load current flows through the collector-emitters, with significantly smaller controlled voltages and currents applied to the bases 114 and 122 as a function of the polarity of the externally applied voltage.

It turns out, however, that the DSDB-BJT of PNP construction in the arrangement of FIG. 2 suffers from an inability to adequately lower the forward voltage drop V_{CEON} across the device when conductive. That is, for the DSDB-BJT 100 of FIG. 1, the forward voltage drop V_{CEON} across the device can be reduced by injection of minority carriers into the bulk region or base region. Biasing the base on the same side of the device of which the collector-emitter is acting as the collector further reduces V_{CEON}. The base on the same side of the BTRAN is referred to as the c-base, in contrast to a three-terminal PNP transistor in which the base is on the opposite side from the collector.

The inventors of the present specification found that lowering of the forward voltage drop V_{CEON} across a DSDB-BJT of PNP construction can be achieved if the main load current through the PNP device is carried through the bases, rather than the collector-emitters, and with minority carriers being provided and/or injected through the collector-emitter on the electrically more positive side of the device.

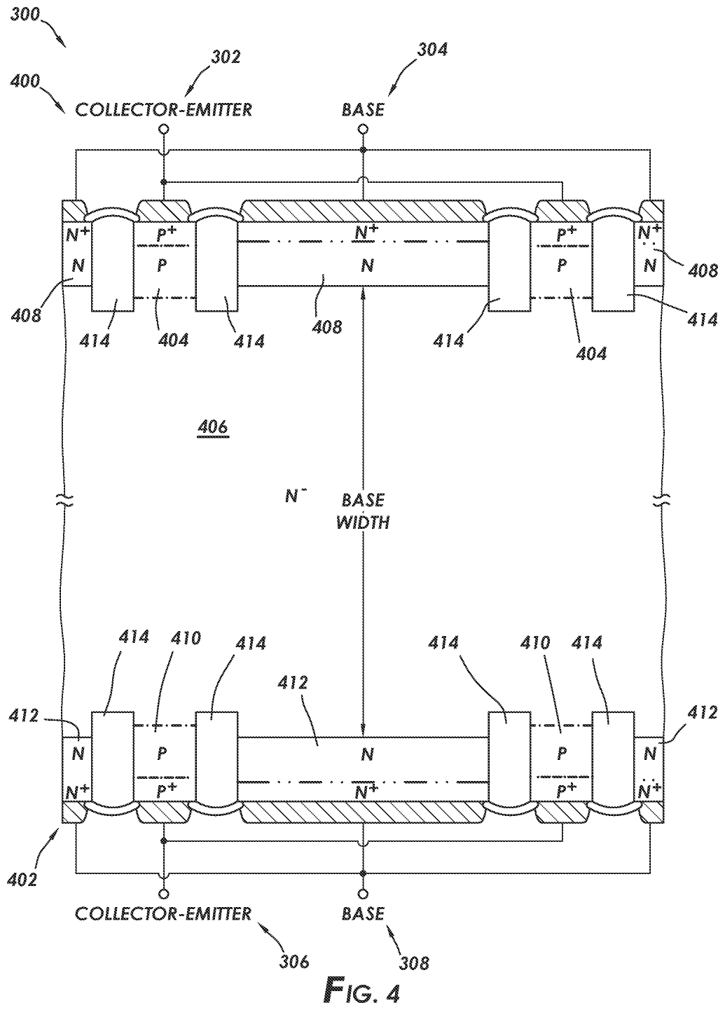

FIG. 3 shows a partial block diagram, partial electrical schematic, of a power module using a DSDB-BJT of PNP construction in accordance with various embodiments. In particular, visible in FIG. 3 is a DSDB-BJT 300 defining an upper collector-emitter 302, an upper base 304, a lower collector-emitter 306, and a lower base 308. As shown by the circuit symbol, the DSDB-BJT 300 is of PNP construction but with a continuous base region ranging from region 304 to region 308. In related-art NPN or PNP devices, the base region is sandwiched by the collector and emitter. In order to control conduction of the DSDB-BJT 300, the DSDB-BJT 300 is associated with a driver circuit. In particular, the upper collector-emitter 302 and the upper base 304 may be associated with an upper driver 310, and the lower collector-emitter 306 and lower base 308 may be associated with a lower driver 312. The upper driver 310 is designed and constructed to selectively: float the upper collector-emitter 302; float the upper base 304; short the upper collector-emitter 302 to the upper terminal 314; and inject minority carriers into the drift region between the upper base 304 and the lower base 308. Similarly, the lower driver 312 is designed and constructed to selectively: float the lower collector-emitter 306; float the lower base 308; short the lower collector-emitter 306 to the lower terminal 316; and inject minority carriers into the drift region between the lower base 308 and the upper base 304. Injection of minority carriers into the drift region significantly lowers the V_{CEON} of the DSDB-BJT 300 during periods of conduction.

In the example of FIG. 3 the DSDB-BJT 300 is arranged for cascode operation with current flowing in either direction. In particular, the DSDB-BJT 300 is associated with a lower electrically-controlled switch (hereafter just lower-main switch 318) coupled between the lower base 308 and the lower terminal 316. The lower-main switch 318 is selected and implemented to interrupt the load current from the upper terminal 314, through the bases 304 and 308, and to the lower terminal 316 when the externally applied voltage is more positive on the upper terminal 314. Relatedly, the DSDB-BJT 300 is associated with an upper electrically-controlled switch (hereafter upper-main switch 320) coupled between the upper terminal 314 and the upper base 304. The upper-main switch 320 is selected and implemented to interrupt the load current from the lower terminal 316, through the bases 308 and 304, and to the upper terminal 314 when the externally applied voltage is more positive on the lower terminal 316. Thus, in the arrangement of FIG. 3 using a DSDB-BJT 300 of PNP construction, and contrary the arrangement of FIG. 2, the main load current flows through bases 304 and 308 as controlled by voltages and currents applied to the upper collector-emitter 302 and the lower collector-emitter 306. The specification now turns to an example DSDB-BJT 300 in greater detail.

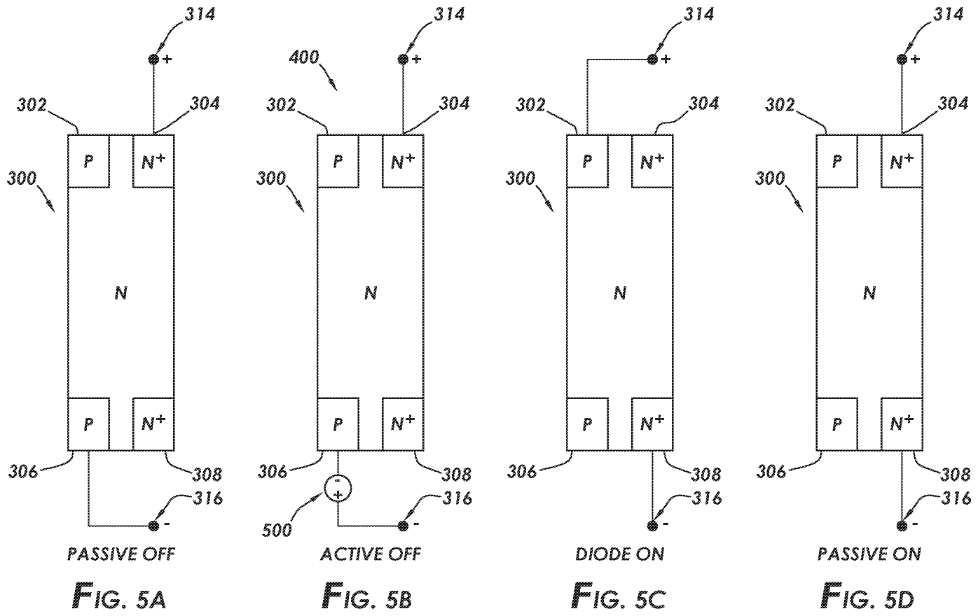

FIG. 4 shows a cross-sectional elevation view of an example DSDB-BJT of PNP construction. In particular, FIG. 4 shows the DSDB-BJT 300 having an upper face or upper side 400 and a lower face or lower side 402. The designations “upper” and “lower” are arbitrary and used merely for convenience of the discussion. The upper side 400 faces a direction opposite the lower side 402. Stated differently, an outward pointing vector normal to the upper side 400 (the vector not specifically shown) points an opposite direction with respect to an outward pointing vector normal to the lower side 402 (the vector not specifically shown).

The upper side 400 includes collector-emitter regions 404 which form a junction with the drift region or bulk substrate 406. The upper side 400 further defines base regions 408 disposed between the collector-emitter regions 404. The collector-emitter regions 404 are coupled together to form the upper collector-emitter 302. The base regions 408 are coupled together to form the upper base 304. Similarly, the lower side 402 includes lower collector-emitter regions 410 which form a junction with the bulk substrate 406. The lower side 402 further defines lower base regions 412 disposed between the lower collector-emitter regions 410. The lower collector-emitter regions 410 are coupled together to form the lower collector-emitter 306. The lower base regions 412 are coupled together to form the lower base 308.

In the example DSDB-BJT 300, the collector-emitter regions 404 and 410 are P-type, and the base regions 408 and 412 are N-type. In the example system, a shallow P+ region provides ohmic contact from collector-emitter regions 404 and 410 to the metallization layer(s) (not specifically numbered) and thus the respective collector-emitters 302 and 306. Further in the example system, shallow N+ contact doping provides ohmic contact from base regions 408 and 412 to the metallization layer(s) (not specifically numbered) and thus the respective bases 304 and 308. In this example, optional dielectric-filled trenches 414 provide lateral separation between base regions and collector-emitter regions.

In example cases, the various structures and doping associated with the upper side 400 are meant to be mirror images of the various structures and doping associated with the lower side 402. However, in some cases the various structures and doping associated with the upper side 400 are constructed at different times than the various structures and doping on the lower side 402, and thus there may be slight differences in the structures and doping as between the two sides, the differences attributable to manufacturing tolerances, but such does not adversely affect the operation of the device as a bi-directional double-base bipolar junction transistor.

In accordance with example embodiments, and in the claims, the status of a region as a base region or a collector-emitter region is defined based on doping type and formation of junctions. It follows that the status of a terminal or connection as a base or collector-emitter is based on the underlying region to which the terminal is coupled. In particular, a collector-emitter region of DSDB-BJT 300 of PNP construction shall mean a region of P-type doping that forms a junction with a bulk substrate and/or base region of N-type doping. Still referring to FIG. 4, and considering upper collector-emitter region 404, the example upper collector-emitter region 404, being P-type, forms a junction with the bulk substrate 406 of N-type. In the case of the DSDB-BJT 300, the bulk region 406 is effectively a base region because of the contiguous N-type doping (i.e., N⁻in the bulk substrate 406 to N in the base region 408 to N+ used to form the ohmic contact). Portions of the collector-emitter region with varying carrier concentrations but the same doping type (e.g., P transitioning to P+) shall not be considered a different doping type.

Similarly, a base region of the DSDB-BJT 300 shall mean a region of N-type doping that is contiguous with bulk substrate of N-type doping. Still referring to FIG. 4, and considering upper base region 408, the example upper base region 408, being N-type, is contiguous with the bulk substrate of N-type doping. Again, in the case of the DSDB-BJT 300, the bulk substrate 406 is effectively a base region because of the contiguous N-type doping. Portions of the base region with varying carrier concentrations but the same doping type (e.g., N⁻ transitioning to N and then transitioning to the N⁻) shall not be considered a different doping type.

Thus, the status of a terminal or connection as a base or collector-emitter is not defined by the path of the main load current and/or the locations at which control voltages or current are applied; rather, the status of a terminal or connection as a base or collector-emitter is defined by the doping types within transistor device. Electrically tracing from the upper base 304 to the lower base 308, only N-type regions are present, with the varying carrier concentrations not changing the fact that from the upper base 304 to the lower base 308 is all N-type region. However, from the upper collector-emitter 302 to the lower collector-emitter 306 there are PN junctions—the P-type upper collector-emitter region 404 forms a junction with the N-type bulk substrate 406, and the N-type bulk substrate forms a junction with the P-type lower collector-emitter region 410.

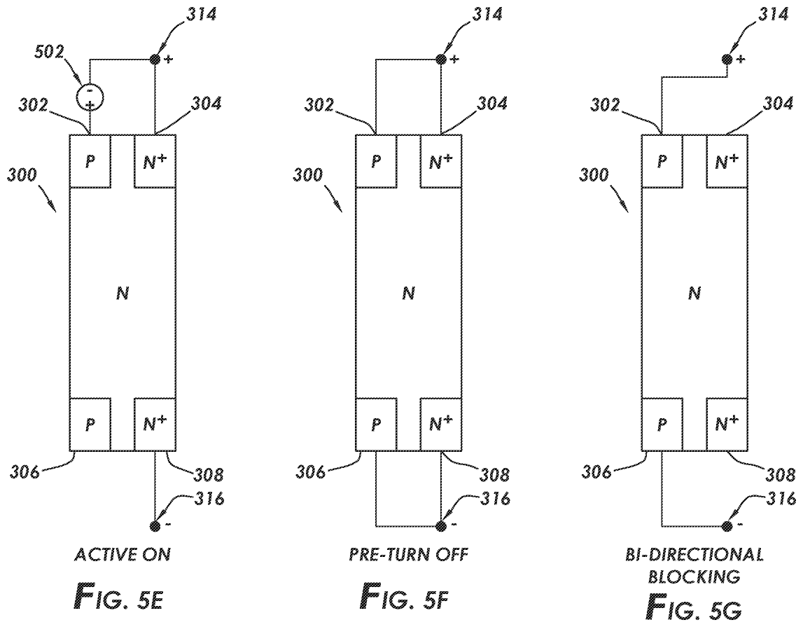

FIGS. 5A-5G show a cross-sectional view of a DSDB-BJT of PNP construction in shorthand form, with example external electrical connections, to illustrate several operational states. In particular, FIGS. 5A-5G show seven example states of the DSDB-BJT 300 arranged for the main load current to be carried across or through the base regions, the seven states being (from left to right): passive off (FIG. 5A); active off (FIG. 5B); diode on (FIG. 5C); passive on (FIG. 5D); active on (FIG. 5E); pre-turn off (FIG. 5F); and bi-directional blocking (FIG. 5G). Each will be addressed in turn.

Referring initially to FIG. 5A, FIG. 5A shows the example upper terminal 314 and lower terminal 316. Between the upper terminal 314 and the lower terminal resides the DSDB-BJT 300 shown in shorthand form and defining the upper collector-emitter 302, the upper base 304, the lower collector-emitter 306, and the lower base 308. In the examples of FIGS. 5A-5G, the externally applied voltage is assumed to have the more positive polarity associated with the upper terminal 314 relative to the lower terminal 316. In the example passive-off arrangement of FIG. 5A, the DSDB-BJT 300 has the upper collector-emitter 302 electrically floated, the upper base 304 is coupled to the upper terminal 314, the lower collector-emitter 306 is coupled to the lower terminal 316, and the lower base 308 is electrically floated. In the arrangement of FIG. 5A, in some cases the DSDB-BJT 300 may have a breakdown voltage of 600 Volts or greater, and in some cases about 1200 Volts. Thus, no appreciable current flows through the DSDB-BJT 300 because of the reversed biased PN junction formed between the lower collector-emitter 306 and the upper base 304. The example state of FIG. 5A is referred as “passive off” because the electrical arrangement of FIG. 5A can be implemented with purely passive components (e.g., diodes and resistors), and thus a driver circuit need not have operational power to implement the arrangement of FIG. 5A.

FIG. 5B shows an example active-off arrangement of the DSDB-BJT 300. In particular, the upper collector-emitter 302 is electrically floated, the upper base 304 is coupled to the upper terminal 314, the lower collector-emitter 306 is coupled to the lower terminal 316 by way of a voltage source 500, and the lower base 308 is electrically floated. The voltage source 500 provides a negative bias to the lower collector-emitter 306. As will be discussed in greater detail below, the voltage source 500 may hasten the transition of the DSDB-BJT 300 to the non-conductive state in the transition from one of the conductive states (also discussed below) to the non-conductive state. In the arrangement of FIG. 5B, in some cases the DSDB-BJT 300 may have a breakdown voltage of 600 Volts or greater, and in some cases about 1200 Volts. Thus again, in the active-off arrangement no appreciable current flows through the DSDB-BJT 300 because of the reversed biased PN junction formed between the lower collector-emitter 306 and the upper base 304. The example state of FIG. 5B is referred as “active off” because in the electrical arrangement of FIG. 5B the associated driver circuit uses operational power to implement the arrangement (e.g., to power the voltage source 500).

FIG. 5C shows an example diode-on arrangement of the DSDB-BJT 300. In particular, the upper collector-emitter is coupled to the upper terminal 314, the upper base 304 is electrically floated, the lower collector-emitter 306 is electrically floated, and the lower base 308 is coupled to the lower terminal 316. In the diode-on arrangement, the PN junction formed by the upper collector-emitter 302 and the bulk substrate is forward biased, and thus current flows from the upper terminal 314 to the lower terminal 316. The voltage drop across the DSDB-BJT 300 in the arrangement of FIG. 5C is about a diode forward voltage drop, around 0.7 Volts. The diode-on arrangement of FIG. 5C is presented for consistency of descriptions with the diode-on arrangement of a DSDB-BJT of NPN construction (not shown), but in practice the diode-on arrangement may only be used in limited circumstances, or not at all.

FIG. 5D shows an example passive-on arrangement of the DSDB-BJT 300. In particular, the upper collector-emitter 302 is electrically floated, the upper base 304 is coupled to the upper terminal 314, the lower collector-emitter 306 is electrically floated, and the lower base 308 is coupled to the lower terminal 316. The voltage drop across the DSDB-BJT 300 in the arrangement of FIG. 5D is based on the substrate resistance (e.g., for a 260 μm thick substrate, about 2 ohms). The example state of FIG. 5D is referred as “passive on” because the conductive state does not involve injection of charge carriers in an attempt to lower the forward voltage drop V_{CEON}, as shown in the active-on arrangement of FIG. 5E.

FIG. 5E shows an example active-on arrangement of the DSDB-BJT 300. In particular, the upper collector-emitter 302 is coupled to the upper terminal 314 by way of a voltage source 502, the upper base 304 is coupled to the upper terminal 314, the lower collector-emitter 306 is electrically floated, and the lower base 308 is coupled to the lower terminal 316. The voltage source 502 provides a positive bias to the upper collector-emitter 302 relative to the upper base 304, and the voltage source 502 may provide any suitable bias voltage (e.g., 0.2V−2V). The voltage source 502 injects charge carriers across the PN junction into the bulk substrate, which lowers forward voltage drop V_{CEON} from base-to-base to about 0.2V for 30 Amps (A) of main current flow through the bases, compared to about 10-20V in the absence of charge carrier injection.

FIG. 5F shows an example pre-turn-off arrangement of the DSDB-BJT 300. In particular, the upper collector-emitter 302 is coupled to the upper terminal 314, the upper base 304 is coupled to the upper terminal 314, the lower collector-emitter 306 is coupled to the lower terminal 316, and the lower base 308 is coupled to the lower terminal 316. An equivalent arrangement may be to omit the coupling of the upper collector-emitter 302 to the upper terminal 314. In the pre-turn-off arrangement of FIG. 5F the DSDB-BJT 300 resistance across the terminals 314 and 316 increases while extra minority carriers are pushed out of the base region. The highest resistance occurs when the base region is back to intrinsic doping density (e.g., specific resistance Rsp could increase from 0.2 mOhm·cm² to 2 Ohm·cm² when minority carrier density decreases from about 1E17/cm³ (high minority injection at on state) to about 5E13/cm³ (substrate intrinsic doping)). The change in minority carrier density increases the voltage drop between the upper terminal 314 and the lower terminal 316. For example, for a 30A load with 0.2 mOhm·cm² Rsp, the pre-turn-off arrangement of FIG. 5F presents about a 60V drop from the upper terminal 314 to the lower terminal 316.

In the example bi-directional blocking of FIG. 5G, for the DSDB-BJT 300 the upper collector-emitter 302 is coupled to the upper terminal 314, the upper base 304 is electrically floated, the lower collector-emitter 306 is coupled to the lower terminal, and the lower base 308 is electrically floated. Thus, no appreciable current flows through the DSDB-BJT 300. In the arrangement of FIG. 5G, the breakdown voltage of the DSDB BJT 300 depends on the reverse PN junction breakdown voltages, in either polarity. The reverse PN junction breakdown voltage is determined by the junction profile, considering tradeoffs with the V_{CEON}. For example, for 300 μm thick N-type substrate of 5E13/cm³ doping, the breakdown voltage between the P- and N-type regions can be more than 1200V.

In many circumstances, the DSDB-BJT 300 will be arranged to transition from either the passive-off arrangement of FIG. 5A or active-off arrangement of FIG. 5B directly to the active-on arrangement of FIG. 5E without implementing an intermediate arrangement or state. That is, the diode-on arrangement of FIG. 5C and the passive-on arrangement of FIG. 5D are optional configurations, but nevertheless may find use in some circumstances. With the respect to transitions from conductive to non-conductive, in many circumstances the DSDB-BJT 300 will be transitioned from the active-on arrangement of FIG. 5E directly to the active-off arrangement of FIG. 5B, the passive-off arrangement of FIG. 5A, or the bi-directional blocking arrangement of FIG. 5G without implementing an intermediate arrangement or state. That is, the diode-on arrangement of FIG. 5C, the passive-on arrangement of FIG. 5D, and the pre-turn-off arrangement of FIG. 5F are optional intermediate configurations in the transition from conductive to non-conductive, but nevertheless may find use in some circumstances.

The examples of FIGS. 5A-5G are for the situation of the externally applied voltage having a positive polarity at the upper terminal 314. However, the example DSDB-BJT 300 is a symmetrical device, and now understanding how to control current flow through the DSDB-BJT with example polarity shown, control of current flow in the opposite direction directly follows.

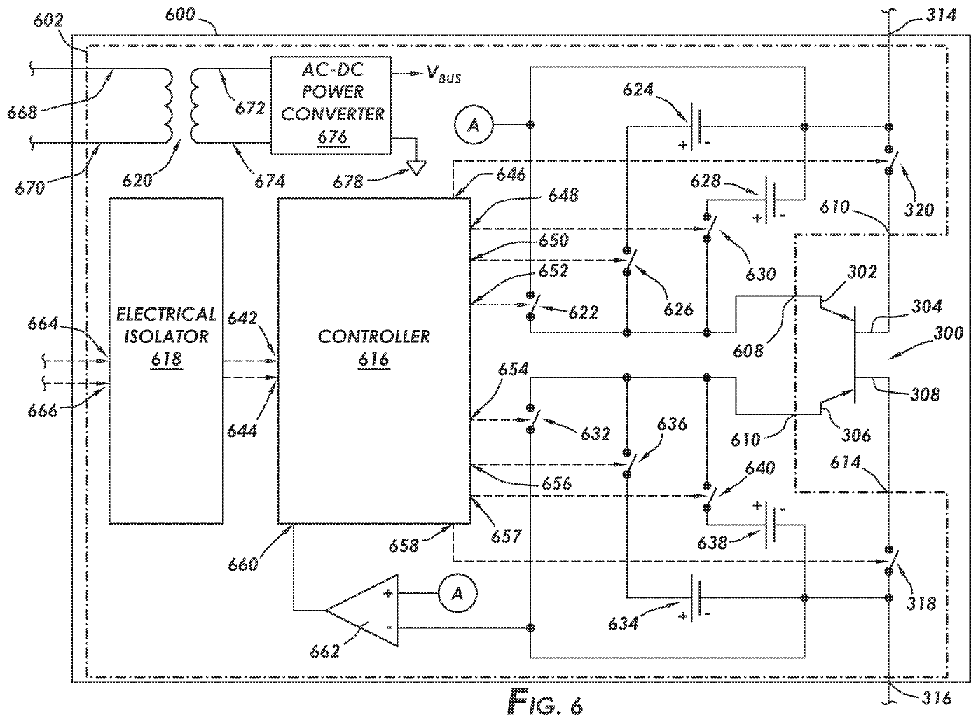

FIG. 6 shows a partial block diagram, partial electrical schematic, of an example power module or switch assembly. In particular, the example switch assembly 600 comprises the DSDB-BJT 300 of PNP construction and a driver 602. The DSDB-BJT 300 is shown by way of an example circuit symbol having two emitters and two bases. The circuit symbol shows the upper collector-emitter 302, the upper base 304, the lower collector-emitter 306, and the lower base 308. The example driver 602 defines an upper collector-emitter terminal 608 coupled to the upper collector-emitter 302, an upper-conduction terminal 610 coupled to the upper base 304, a lower collector-emitter terminal 612 coupled to the lower collector-emitter 306, and a lower-conduction terminal 614 coupled to the lower base 308. The upper base 304 is coupled to the upper terminal 314 of the switch assembly 600 by way of the upper-conduction terminal 610. The lower base 308 is coupled to the lower terminal 316 of the switch assembly 600 by way of the lower-conduction terminal 614.

The example driver 602 comprises a controller 616, an electrical isolator 618, and an isolation transformer 620. In order to place the DSDB-BJT 300 in the various conduction and non-conduction modes, the example driver 602 includes a plurality of electrically-controlled switches and sources of charge carriers. In particular, the example driver 602 comprises a switch 622 that has its first lead coupled to the upper terminal 314, a second lead coupled to the upper collector-emitter 302, and a control input coupled to the controller 616. The example switch 622 is shown as a single-pole, single-throw switch, but in practice the switch 622 may be a FET with the control input being a gate of the FET. Thus, when the switch 622 is made conductive by assertion of its control input, the upper collector-emitter 302 is coupled to the upper terminal 314.

The driver 602 further comprises a source of charge carriers 624 illustratively shown as a battery. The source of charge carriers 624 has a negative lead coupled to the upper terminal 314. Another electrically-controlled switch 626 (hereafter just switch 626) has a first lead coupled to the positive terminal of the source of charge carriers 624, a second lead coupled to the upper collector-emitter 302, and a control input coupled to the controller 616. The example switch 626 is also shown as a single-pole, single-throw switch, but in practice the switch 626 may be a FET with the control input being the gate of the FET. Thus, when the switch 626 is conductive, the source of charge carriers 624 is coupled between the upper terminal 314 and the upper collector-emitter 302. The driver 602 further comprises another source of charge carriers 628 illustratively shown as a battery. The source of charge carriers 628 has a positive lead coupled to the upper terminal 314. Another electrically-controlled switch 630 (hereafter just switch 630) has a first lead coupled to the negative terminal of the source of charge carriers 628, a second lead coupled to the upper collector-emitter 302, and a control input coupled to the controller 616. The example switch 630 is also shown as a single-pole, single-throw switch, but in practice the switch 630 may be a FET with the control input being the gate of the FET. Thus, when the switch 630 is conductive, the source of charge carriers 628 is coupled between the upper terminal 314 and the upper collector-emitter 302.

The driver 602 further comprises the upper-main switch 320 that has a first lead coupled to the upper terminal 314, a second lead defining the upper-conduction terminal 610 coupled to the upper base 304, and a control input coupled to the controller 616. As before, the example upper-main switch 320 is shown as a single-pole, single-throw switch, but in practice the upper-main switch 320 may be a FET with the control input being a gate of the FET. Thus, when the upper-main switch 320 is made conductive, such as by assertion of its control input, the upper terminal 314 is coupled to the upper base 304.

Turning now to lower side of the DSDB-BJT 300, the example driver 602 further comprises a switch 632 that has a first lead coupled to the lower terminal 316, a second lead coupled to the lower collector-emitter 306, and a control input coupled to the controller 616. The example switch 632 is shown as a single-pole, single-throw switch, but in practice the switch 632 may be a FET with the control input being a gate of the FET. Thus, when the switch 632 is made conductive by assertion of its control input, the lower collector-emitter 306 is coupled to the lower terminal 316.

The driver 602 further comprises a source of charge carriers 634 illustratively shown as a battery. The source of charge carriers 634 has a negative lead coupled to the lower terminal 316. Another electrically-controlled switch 636 (hereafter just switch 636) has a first lead coupled to the positive terminal of the source of charge carriers 634, a second lead coupled to the lower collector-emitter 306, and a control input coupled to the controller 616. The example switch 636 is shown as a single-pole, single-throw switch, but in practice the switch 636 may be a FET with the control input being the gate of the FET. Thus, when the switch 636 is conductive, the source of charge carriers 634 is coupled between the lower terminal 316 and the lower collector-emitter 306. The example driver 602 further comprises another source of charge carriers 638 illustratively shown as a battery. The source of charge carriers 638 has a positive lead coupled to the lower terminal 316. Another electrically-controlled switch 640 (hereafter just switch 640) has a first lead coupled to the negative terminal of the source of charge carriers 638, a second lead coupled to the lower collector-emitter 306, and a control input coupled to the controller 616. The example switch 640 is shown as a single-pole, single-throw switch, but in practice the switch 640 may be a FET with the control input being the gate of the FET. Thus, when the switch 640 is conductive, the source of charge carriers 638 is coupled between the lower terminal 314 and the lower collector-emitter 306.

The example driver 602 further comprises the lower-main switch 318 that has a first lead coupled to the lower terminal 316, a second lead defining the lower-conduction terminal 614 coupled to the lower base 308, and a control input coupled to the controller 616. As before, the example lower-main switch 318 is shown as a single-pole, single-throw switch, but in practice the lower-main switch 318 may be a FET with the control input being a gate of the FET. Thus, when the lower-main switch 318 is conductive, such as by assertion of its control input, the lower terminal 314 is coupled to the lower base 308.

The controller 616 defines control inputs 642 and 644, and control outputs 646, 648, 650, 652, 654, 656, 657, and 658 coupled to the control inputs of the switches 320, 630, 626, 622, 632, 636, 640, and 318, respectively. When the control input 642 is asserted, the controller 616 is designed and constructed to arrange the DSDB-BJT 300 for conduction from the upper terminal 314 to the lower terminal 316. Oppositely, when the control input 642 is de-asserted, the controller 616 is designed and constructed to arrange the DSDB-BJT 300 to block current flow from the upper terminal 314 to the lower terminal 316. Similarly, when the control input 644 is asserted, the controller 616 is designed and constructed to arrange the DSDB-BJT 300 for conduction from the lower terminal 316 to the upper terminal 314. And oppositely, when the control input 644 is de-asserted, the controller 616 is designed and constructed to arrange the DSDB-BJT 300 to block current flow from the lower terminal 316 to the upper terminal 314. When the control inputs 642 and 644 are both asserted, the controller 816 arranges the DSDB-BJT 300 for current flow in both directions (e.g., AC breaker service), and when the control inputs 642 and 644 are both de-asserted, the controller 616 blocks current flow in both directions.

The arrangement of the DSDB-BJT 300 to be non-conductive is dependent upon the polarity of the applied voltage. Thus, the example controller 616 may further define a polarity input 660 that receives a Boolean indication of the applied polarity. In the example driver 602, a comparator 662 has a first input coupled to the upper terminal 314 (the connection shown by bubble “A”) and a second input coupled to the lower terminal 316. The comparator 662 defines a compare output coupled to the polarity input 660. While FIG. 6 shows the first and second inputs coupled directly to the respective conduction terminals, in practice the voltage across the DSDB-BJT 300 when non-conductive may be large (e.g., 1200V) and thus each of the first and second inputs may be coupled to their respective conduction terminals by way of respective voltage divider circuits. In yet still further cases, the applied polarity may be determined by systems and devices external to the switch assembly 600, and a Boolean signal sent across the electrical isolator 618 to the polarity input 660.

Transitioning the DSDB-BJT 300 from being non-conductive, to conductive, and then back to non-conductive may be a multistep process. To implement the multistep process, the controller 616 may be individual circuit components, an application specific integrated circuit (ASIC), a microcontroller with controlling software, a reduced-instruction-set computing (RISC), a digital signal processor (DSP), a processor with controlling software, a programmable logic device (PLD), a field programmable gate array (FPGA), a programmable system-on-a-chip (PSOC), and/or combinations, configured to read the control inputs 642 and 644, read the polarity input 660, and drive control outputs to implement the mode transitions of the DSDB-BJT 300.

In example systems, the switch assembly 600 is electrically floated. In order to receive the control inputs 642 and 644 in the electrical domain of the switch assembly 600, the example driver 602 implements the electrical isolator 618. The example electrical isolator 618 may take any suitable form, such as optocouplers or capacitive isolation devices. Regardless of the precise nature of the electrical isolator 618, external control signals (e.g., Boolean signals) may be coupled to control inputs 664 and 666 of the electrical isolator 618. The electrical isolator 618, in turn, passes the control signals through to the electrical domain of the switch assembly 600. In the example, the external control signals are passed through to become the control input 642 and 644 of the controller 616.

Turning now to the isolation transformer 620. Various devices within the switch assembly 600 may use operational power. For example, the controller 616 may use a bus voltage and power to enable implementation of the various modes of operation of the DSDB-BJT 300. Further, the sources of charge carriers within system may in practice be implemented as individual voltage sources in the form of switching power converters, or individual current sources also implemented using switching power converters. The switching power converters implementing the sources of charge carriers may use bus voltage and power. In order to provide operational power within the electrical domain of the switch assembly 600, the isolation transformer 620 is provided. External systems (not specifically shown) may provide an alternating current (AC) signal across the primary leads 668 and 670 of the isolation transformer 620 (e.g., 15V AC). The isolation transformer 620 creates an AC voltage on the secondary leads 672 and 674. The AC voltage on the secondary of the isolation transformer 620 may be provided to an AC-DC power converter 676, which rectifies the AC voltage and provides power by way of bus voltage VBUS (e.g., 3.3V, 5V, 12V) with respect to a common 678. The power provided by the AC-DC power converter 676 may be used by the various components of the switch assembly 600. In other cases, multiple isolation transformers may be present (e.g., one for each side of the DSDB-BJT). Further still, a single isolation transformer with multiple secondary windings may be used. The discussion now turns to example arrangements for making the DSDB-BJT 300 conductive and/or non-conductive in the context of the switch assembly 600.

Consider, as an example, a situation in which the applied voltage has the positive polarity on the upper terminal 314. Further consider that the control input 664 applied to the electrical isolator 618 is de-asserted, and thus a control signal applied to the control input 642 of the controller 616 is de-asserted. Based on the de-asserted state of the control input 642, the controller 616 is designed and constructed to place the DSDB-BJT 300 in the non-conductive arrangement taking into account the applied polarity (e.g., as read by the controller 616 through the polarity input 660). Thus, in the example arrangement the upper-main switch 320 is conductive, the lower main switch 318 is non-conductive and either: 1) switch 632 is conductive (passive off); or 2) switch 640 is conductive (active off). In some examples, the upper-main switch 320 is made conductive by the controller 616 asserting the control output 646. However, in other cases, and as described in greater detail below, the upper-main switch 320 is implemented as a FET with an internal body diode. Thus, the conductivity of upper-main switch 320 may be based, initially at least, on the applied voltage forward biasing the body diode of the FET implementing the upper-main switch 320. A similar arrangement and/or operation may exist for the lower-main switch 318 when arranged for blocking current for the opposite polarity.

Still considering the example arrangement of the positive polarity at the upper terminal 314, now consider that the control signal applied to the control input 664 of the electrical isolator 618 is asserted, and thus the control signal applied to the control input 642 of the controller 616 is asserted. Based on the assertion, in the example switch assembly 600 the controller 616 may be designed and constructed to place the DSDB-BJT 300 directly into the active-on arrangement (FIG. 5E). To that end, the controller 616 may assert the control output 646 (if not already asserted) to make the upper-main switch 320 conductive, assert the control output 650 to make the switch 626 conductive, assert the control output 658 to make the lower-main switch 318 conductive, and de-assert or leave de-asserted the remaining control outputs. In yet still other cases, to place the DSDB BJT 300 in the conductive state, the controller 616 may be designed and constructed to make the switch 626 conductive a predetermined period of time prior (e.g., from about 0.1 μs to 5 μs) to making the lower-main switch 318 conductive. Making the switch 626 conductive prior to the making the lower-main switch 318 conductive may charge the collector-emitter 302 to base 304 capacitance, making the DSDB BJT 300 fully conductive more quickly once the lower-main switch 318 is made conductive.

Optionally, again with the positive polarity at the upper terminal 314, the controller 616 may be designed and constructed to take the DSDB-BJT 300 through an intermediate conductive arrangement before arriving at the active-on arrangement. For example, the controller 616 may momentarily place the DSDB-BJT 300 in the passive-on arrangement (FIG. 5D) by asserting the control output 646 to make the upper-main switch 320 conductive, asserting the control output 658 to make the lower-main switch 318 conductive, and de-asserting or leaving de-asserted the remaining control outputs. When used, the passive-on arrangement may last a predetermined period (e.g., from about 0.1 μs to 5 μs). As another example of an intermediate conductive state, the controller 616 may momentarily place the DSDB-BJT 300 in the diode-on arrangement (FIG. 5C) by asserting the control output 652 to make the switch 622 conductive, asserting the control output 658 to make the lower-main switch 318 conductive, and de-asserting or leaving de-asserted the remaining control outputs. When used, the diode-on arrangement may last a predetermined period (e.g., from about 0.1 μs to 5 μs). In practice, the upper-main switch 320 may have an internal body diode, or be associated with discrete parallel diode, such that the diode-on arrangement cannot be implemented, as the body diode or discrete parallel diode would be forward biased when the positive polarity is at the upper terminal 314. A similar inability to implement the diode-on arrangement may exist when the positive polarity is at the lower terminal 316 if the lower-main switch 318 has a body diode or a discrete parallel diode. Nevertheless, after the intermediate conductive arrangement, the controller 616 places the DSDB-BJT 300 in the active-on arrangement.

In the active-on arrangement, and for the positive polarity at the upper terminal 314, the source of charge carriers 624 injects charge carriers into the upper collector-emitter 302. Injecting charge carriers into the upper collector-emitter 302 increases the number of charge carriers in the drift region of the DSDB-BJT 300, which lowers the V_{CEON} measured across the bases 304 and 308. In one example, the source of charge carriers 624 injecting charge carriers may lower the V_{CEON} across the bases 304 and 308 to about 0.2V for about 30A to 100A of current flow through the bases 304 and 308. The source of charge carriers 624 may take any suitable voltage between and including 0.5V and 5.0V, in some cases between 0.6V and 1.5V

Still referring to FIG. 6, and still considering the positive polarity on the upper terminal 314. Further consider that the control input 664 applied to the electrical isolator 618 transitions from asserted to de-asserted, and thus a control signal applied to the control input 642 of the controller 616 transitions from asserted to de-asserted. Based on the transition, the controller 616 is designed and constructed to once again place the DSDB-BJT 300 in the non-conductive arrangement. In example cases, the controller 616 may, from the conductive state of the DSDB-BJT 300, directly implement the passive-off arrangement or the active-off arrangement as previously discussed. In other cases, the controller 616 may turn off the switch 626 a predetermined amount of time before (e.g., from about 0.1 μs to 5 μs) opening the lower-main FET 318, which lower minority carriers in the drift region and thereby lowers the peak of the commutation current and/or shorten the duration of the commutation current. Moreover, with respect to the timing of changing the states of the upper-main switch 320 and the lower-main switch 318, when transitioning to the non-conductive state of the DSDB-BJT 300 with the assumed polarity, the lower-main switch 318 may be made non-conductive, but the upper-main switch 320 may remain in the conductive state for a predetermined period of time (e.g., about 450 nano-seconds or less) as the current through the switch assembly 600 falls, which may reduce the reverse recovery time of the body diode associated with the upper-main switch 320.

Optionally, the controller 616 may be designed and constructed to take the DSDB-BJT 300 through an intermediate conductive arrangement before arriving at the non-conductive arrangement. For example, the controller 616 may momentarily place the DSDB-BJT 300 in the diode-on arrangement (FIG. 5C), the passive-on arrangement (FIG. 5D), or the pre-turn-off arrangement (FIG. 5F). When used, the intermediate arrangements between active on and active off may last a predetermined period (e.g., from about 0.1 μs to 5 μs).

The example operation discussed with respect to FIG. 6 was with the positive polarity on the upper terminal 314. Again, however, the example DSDB-BJT 300 and the related driver are symmetrical, and now understanding how to arrange the DSDB-BJT 300 into the various conductive and non-conductive states, control of current flow in the opposite direction directly follows.

The switch assembly of FIG. 6 shows the example DSDB-BJT 300 arranged for cascode operation. In such an arrangement, the interruption of current flow through the device (e.g., in the transition from conductive to non-conductive) is implemented primarily by the upper-main switch 320 and the lower-main switch 318. For example, with the positive polarity on the upper terminal 314, current flow through the switch assembly 600 is initially interrupted by the lower-main switch 318, and then the further blocking is implemented by the DSDB-BJT 300. Oppositely, with the positive polarity on the lower terminal 316, current flow through the switch assembly 600 is initially interrupted by the upper-main switch 320, and then the further blocking is implemented by the DSDB-BJT 300. It follows that since the blocking is implemented by the DSDB-BJT 300, the breakdown voltages of the upper-main switch 320 and the lower-main switch 318 may be significantly lower than the breakdown voltage of the DSDB-BJT 300. For example, each of the upper-main switch 320 and lower-main switch 318 may have breakdown voltages of 100V or less, in some cases 80V or less, while the breakdown voltage of the DSDB-BJT 300 may be 600V or greater, and in some cases about 1200V.

In the transition from a conductive state through the bases 304 and 308 to a non-conductive state, a relatively small amount of current—a shut off current—may flow momentarily through collector-emitter on the side opposite the positive polarity. For example, with the positive polarity on the upper terminal 314 and current flow from the upper base 304, through the DSDB-BJT 300, and out the lower base 308, interrupting the current flow by the lower-main switch 318 may cause a shutoff current to flow momentarily through the lower collector-emitter 306. Stated differently, when the load current through the DSDB-BJT 300 is interrupted by the lower-main switch 318, the shutoff current is commutated through the lower collector-emitter 306 for a short period of time as the lower PN junction becomes reversed biased (keeping in mind that, for the assumptions, the lower collector-emitter 306 is electrically floated during conduction). Thus, the passive-off arrangement (FIG. 5A) and the active-off arrangement (FIG. 5B) provide a current path for the shutoff current to the lower terminal 316. In the case of the active-off arrangement (FIG. 5B), the source of charge carriers 638 (corresponding to voltage source 500 of FIG. 5B) may hasten the transition to the non-conductive state of the DSDB-BJT 300 by extracting charge carriers from the bulk region and more quickly reverse biasing the PN junction formed between the lower collector-emitter 306 and the bulk region. Now understanding the commutation of the current through the lower collector-emitter 306 when the more positive voltage is at the upper terminal 314, an equivalent discussion of commutation current through the upper collector-emitter 302 when the more positive voltage is at the lower terminal 316 follows directly.

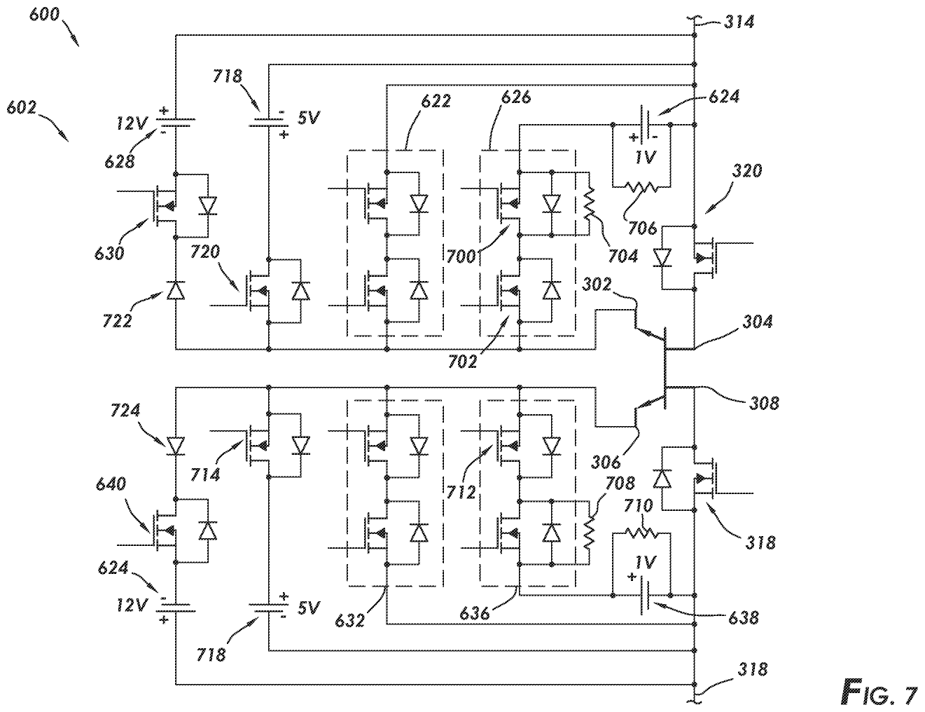

FIG. 7 shows a partial electrical schematic of an example switch assembly. In particular, FIG. 7 shows the example DSDB-BJT 300 as well as portions of an example driver 602. The driver 602 may likewise have the isolation transformer, the AC-DC power converter, the electrical isolator, the controller, and the comparator, but those components are omitted from the shorthand notation of FIG. 7. For purposes of discussion, the upper side FIG. 7 shows the switches 320, 622, 626, and 630, as well as the example sources of charge carriers 624 and 628. The lower side shows the switches 318, 632, 636, and 640, as well as the example sources of charge carriers 634 and 368.

As alluded to above, many of the switches are implemented as FETs. In the example switch assembly of FIG. 7 the upper-main switch 320 is shown as a FET having a source coupled to the upper terminal 314, a drain coupled to the upper base 304, a gate defining the control input, and a body diode coupled between the source and the drain. When the applied voltage has a positive polarity on the upper terminal 314, the body diode is forward biased making the upper-main switch 320 conductive (without action by the controller 616 (FIG. 6)). During conductive states of the DSDB-BJT 300 the controller 616 drives the gate to make the FET conductive to lower the overall voltage drop. In example cases, the FET used to implement the upper-main switch 320 may have a breakdown voltage of 100V or less, and in some cases about 80V, in spite of the fact the DSDB-BJT 300 may have a breakdown voltage of 600V or more, and in some cases about 1200V.

The example switch 622 is shown as pair of back-to-back FETs. In particular, the switch 622 is shown as a first FET having a source coupled to the upper terminal 314, a second FET having a source coupled to the upper collector-emitter 302, and the drains of the FETs are coupled together. The gates of the FETs may be coupled individually to the controller 616 (FIG. 6), or the gates may be coupled together and driven by the controller 616 as a single unit. The FETs each have a body diode, and in the arrangement shown the cathodes of the body diodes are coupled together. Having back-to-back FETs enables bi-directional current blocking in spite of the presence of the body diodes, as well as bi-directional current flow. With the positive polarity on the upper terminal 314, the switch 622 may be conductive during the optional diode-on arrangement (FIG. 5C) or the optional pre-turn-off arrangement (FIG. 5F). During the active-on arrangement (FIG. 5E), however, the switch 622 may be non-conductive (e.g., to enable other devices to inject charge carriers into the upper collector-emitter 302). Thus, for positive polarity on the upper terminal 314, when the gates are de-asserted the back-to-back FETs block current flow in spite of the body diode of the first FET being forward biased. In situations in which the positive polarity is on the lower terminal 316, the switch 622 may also be conductive in transitions to the passive-off arrangement (though passive off using switch 622 would be with the driver 602 powered). For example, the shutoff current in the passive-off arrangement may be carried by switch 622.

Similarly, switch 626 is shown as a pair of back-to-back FETs. In particular, the switch 626 is shown as a FET 700 having a source coupled to the source of charge carriers 624, a FET 702 having a source coupled to the upper collector-emitter 302, and the drains of the FETs 700 and 702 are coupled together. The gates of the FETs 700 and 702 may be coupled individually to the controller 616 (FIG. 6), or the gates may be coupled together and driven by the controller 616 as a single unit. The FETs 700 and 702 each have a body diode, and in the arrangement shown the cathodes of the body diodes are coupled together. Having back-to-back FETs enables bi-directional current blocking in spite of the presence of the body diodes, as well as bi-directional current flow. With positive polarity on the upper terminal 314, the active-on arrangement may be implemented with the source of charge carriers 624 injecting charge carriers into the upper collector-emitter 302 through the FETs 700 and 702. In other modes, the current flow from the source of charge carriers 624 to the upper collector-emitter 302 may be blocked by the FET 702 in spite of the fact the body diode of the FET 700 may be forward biased by the source of charge carriers 624.

Still considering switch 626 and resistors 704 and 706 (and the corresponding resistors 708 and 710 associated with switch 636 on the lower side), the body diodes may be used to enable a power-up safe mode. That is, the resistors 704 and 706 ensure race conditions at power up of the switch assembly 600 do not cause inadvertent conduction through the DSDB-BJT 300. In particular, the switch assembly 600 may have the upper terminal 314 and lower terminal 316 coupled within an overall system. Voltage may appear across the upper terminal 314 and lower terminal 316, in either polarity, before the AC-DC power converter 676 (FIG. 6) is powered up, and/or before the controller 616 has had an opportunity to bootstrap to an operational state. Consider, as an example, a power up condition in which the positive polarity appears at the lower terminal 316 before the controller 616 is operational. In such a situation, the body diode of the FET implementing the lower-main switch 318 is conductive. Moreover, the body diode of the FET 702 of the switch 626 will be forward biased, causing the shutoff current and/or leakage current to flow from the upper collector-emitter 302 to the upper terminal 314, thus implementing the passive-off arrangement (FIG. 5A). A similar arrangement occurs when the positive polarity appears on the upper terminal 314, with the leakage current flowing through the body diode of FET 712, the resistor 708, and the resistor 710. Thus, even in the absence of control by the controller 616, the DSDB-BJT 300 enters a non-conductive safe mode regardless of the polarity of the voltage applied across the upper terminal 314 and lower terminal 316.

In accordance with the example system, the active-on arrangement (FIG. 5E) may be implemented selectively with different voltages over time. In particular, the example switch assembly 600 further comprises a source of charge carriers 718, illustratively shown as a battery, having a negative lead coupled to the upper terminal 314. A switch, illustratively shown as FET 720, has a source coupled to the positive lead of the source of charge carriers 718, a drain coupled to the upper collector-emitter 302, and a control input or gate coupled to the controller 616 (FIG. 6). With the positive polarity on the upper terminal 314, the active-on arrangement may be initially implemented by the FET 720 and source of charge carriers 718. Thus, in the active-on arrangement the source of charge carriers 718 may initially inject charge carriers into the upper collector-emitter 302 at a first rate. After a predetermined period of time, the controller 616 may be designed and constructed to reduce the rate of charge carrier injection by making FET 720 non-conductive, and substantially simultaneously, making switch 626 conductive and thus injecting charge carriers into the upper collector-emitter 302 at a lower rate using the source of charge carriers 624. That is, once the V_{CEON} is driven low using the source of charge carriers 718, the lowered V_{CEON} may be maintained using the source of charge carriers 624. Now understanding the use of sources of charge carriers 624 and 718 in implementing the active-on arrangement with the positive polarity on the upper terminal 314, an equivalent discussion of implementing the active-on arrangement with the positively polarity on the lower terminal 316 using source of charge carriers 638 and 716 (along with switch 714) follows directly.

Still referring to FIG. 7, and in particular the upper side. Switch 630 is shown as a single FET having a source coupled to the upper collector-emitter 302, a drain coupled to the negative lead of the source of charge carriers 628, a gate defining the control input coupled to the controller 616 (FIG. 6), and a body diode coupled between the source and the drain. The voltage associated with the source of charge carriers 628 may keep the body diode of the FET reversed biased when the FET itself is non-conductive, and thus back-to-back FETs may not be needed with respect to the switch 630. In order to block current flow from the upper terminal 314 to the upper collector-emitter 302 in power loss and/or startup situations, a diode 722 is disposed between the source of the FET and the upper collector-emitter 302. In particular, the diode 722 has its anode coupled to the upper collector-emitter 302 and its cathode coupled to the cathode of the body diode of the switch 630. As discussed above, the switch 630 and source of charge carriers 628 may be used to implement the active-off arrangement when the positive polarity is on the lower terminal 316. When the positive polarity is on the upper terminal 314, a similar function is served by switch 640, source of charge carriers 624, and a diode 724.

FIG. 7 further shows the lower-main switch 318 as a FET having a source coupled to the lower terminal 316, a drain coupled to the lower base 308, a gate defining the control input, and a body diode coupled between the source and the drain. When the positive polarity is on the lower terminal 316, the body diode is forward biased thus making lower-main switch 318 conductive (without action by the controller 616 (FIG. 6)). During conductive states of the DSDB-BJT 300, the controller 616 drives the gate to make the FET conductive to lower the overall voltage drop. In example cases, the FET used to implement the lower-main switch 318 may have a breakdown voltage of 100V or less, and in some cases about 80V, in spite of the fact the DSDB-BJT 100 may have a breakdown voltage of 600V or more, and in some cases about 1200V.

In similar fashion to switch 622, switch 632 may be implemented as back-to-back FETs. Further, in similar fashion switch 636 may be implemented as back-to-back FETs. The description of operation of switches 632 and 636 are duplicative of the descriptions of switches 622 and 626, taking into account the polarity of the applied voltage, and will not be repeated again here so as not to unduly lengthen the description.

When the various switches are implemented as FETs with body diodes as shown in FIG. 7, state transitions may be more easily and quickly implemented by the controller 616 (FIG. 6). Consider, as an example, the positive polarity on the upper terminal 314 and that driver 602 has the DSDB-BJT 300 in the active-on arrangement. In such a situation, the upper-main switch 320 is conductive, the switch 626 or FET 720 is conductive, the lower-main switch 318 is conductive, and the remaining switches are non-conductive. Now consider that driver 602 receives a command to make the DSDB-BJT 300 non-conductive (e.g., de-assertion of control input 642 (FIG. 6)). When the switches are implemented as FETs as shown, arranging the driver 602 to implement active-off mode may involve having the controller 616 (FIG. 6) de-assert all the gates of all the FETs. Upper-main switch 320 remains conductive based on the body diode being forward biased and conductive. The lower-main switch 318 interrupts the current flow and its body diode is reverse biased. The interruption of the current flow commutates the shutoff current to flow through the body diode of FET 712 of switch 636 and resistors 708 and 710. At some point in the example situation, the controller 616 may make switch 640 conductive to implement the active-off arrangement, but the timing is not critical. Stated otherwise, the controller 616 may be designed and constructed to implement the passive-off arrangement momentarily before implementing the active-off arrangement, if nothing more than to reduced timing constraints. A similar discussion follows for interrupting current flow with the positive voltage on the lower terminal 316.

The various sources of charge carriers shown in FIGS. 6 and 7 are illustratively shown as batteries. However, in practice these sources of charge carriers may be individual DC-DC converts, or for sources of charge carriers on the same side with corresponding polarity (e.g., sources of charge carriers 624 and 718), a single DC-DC convert with a controlled voltage output may be implemented. In other cases the DC-DC converters may be implemented as controlled-current sources rather than voltage sources.

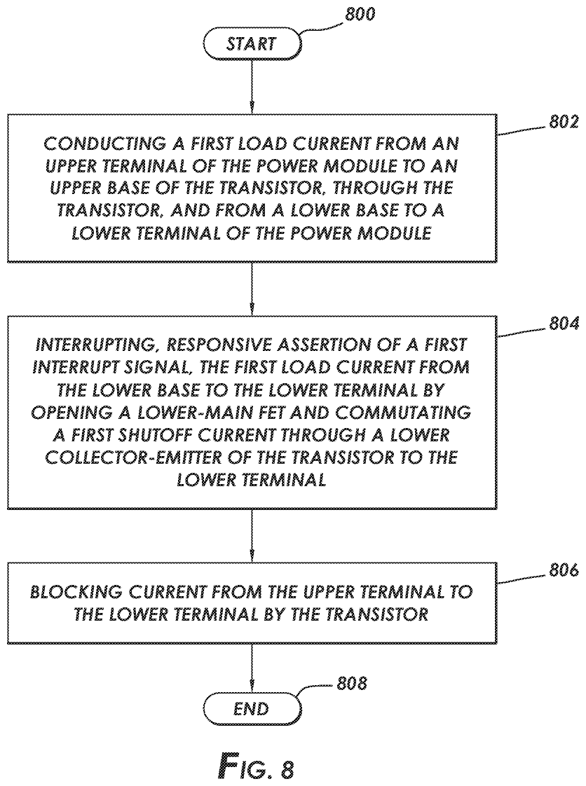

FIG. 8 shows a method in accordance with at least some embodiments. In particular, the method starts (block 800) and comprises: conducting a first load current from an upper terminal of the power module to an upper base of the transistor, through the transistor, and from a lower base to a lower terminal of the power module (block 802); and then responsive assertion of a first interrupt signal interrupting the first load current from the lower base to the lower terminal by opening a lower-main FET and commutating a first shutoff current through a lower collector-emitter of the transistor to the lower terminal (block 804); and blocking current from the upper terminal to the lower terminal by the transistor (block 806). Thereafter, the method ends (block 808).

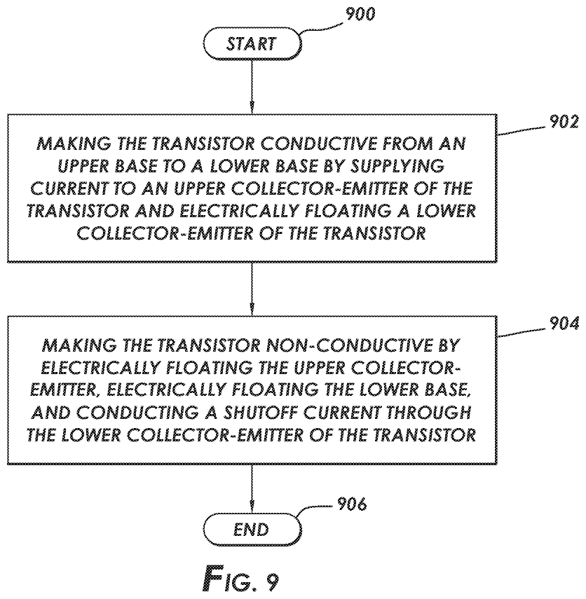

FIG. 9 shows a method in accordance with at least some embodiments. In particular, the method starts (block 900) and comprises: making the transistor conductive from an upper base to a lower base by supplying current to an upper collector-emitter of the transistor and electrically floating a lower collector-emitter of the transistor (block 902); and then making the transistor non-conductive by electrically floating the upper collector-emitter, electrically floating the lower base, and conducting a shutoff current through the lower collector-emitter of the transistor (block 904). Thereafter, the method ends (block 906).

While the upper-main switch and lower-main switch each have a corresponding voltage drop when fully conductive, when implemented as power FETs the forward voltage drops are small (e.g., 0.01V to 0.1V), and in many cases negligible, compared to the forward voltage drop of the associated DSDB-BJT (e.g., 0.2V to 0.6V). Moreover, it is noted that the shutoff current that flows through the collector-emitter on the opposite side from the positive polarity during a transition from conductive to non-conductive may have a peak current about equal to the load current; however, while the collector-emitter regions and connections may not be designed to handle full load current for extended periods of time, the inventors of the present specification found through simulations that given the transient nature of the shutoff current (e.g., 1 μs to 3 μs), even shutoff currents with peaks equal to the load current do not adversely affect operation of the device.

Many of the electrical connections in the drawings are shown as direct couplings having no intervening devices, but not expressly stated as such in the description above. Nevertheless, this paragraph shall serve as antecedent basis in the claims for referencing any electrical connection as “directly coupled” for electrical connections shown in the drawing with no intervening device(s). Moreover, this paragraph shall not negate that a base electrically connected to a collector-emitter through a transistor may be referred to as “directly coupled.”

The above discussion is meant to be illustrative of the principles and various embodiments of the present invention. Numerous variations and modifications will become apparent to those skilled in the art once the above disclosure is fully appreciated. It is intended that the following claims be interpreted to embrace all such variations and modifications.

What is claimed is:

1. A method of operating a power module having a bi-directional double-base bipolar junction transistor, the method comprising:
conducting a first load current from an upper terminal of the power module to an upper base of the transistor, through the transistor, and from a lower base to a lower terminal of the power module; and then responsive assertion of a first interrupt signal
interrupting the first load current from the lower base to the lower terminal by opening a lower-main FET and commutating a first shutoff current through a lower collector-emitter of the transistor to the lower terminal; and
blocking current from the upper terminal to the lower terminal by the transistor.

2. The method of claim 1:
wherein, during the conducting, the method further comprises injecting charge carriers into an upper collector-emitter; and
the method further comprising, responsive to the assertion of the first interrupt signal, ceasing the injection of charge carriers into the upper collector-emitter.

3. The method of claim 2 wherein ceasing injection of charge carriers further comprises ceasing injection of charge carriers a non-zero predetermined time before the interrupting the first load current by opening the lower-main FET.

4. The method of claim 1:
wherein interrupting the first load current further comprises interrupting the first load current with the lower-main FET having a breakdown voltage of 100 Volts or less; and
wherein blocking current further comprises blocking at an applied voltage across the upper terminal and the lower terminal of 600 Volts or greater.

5. The method of claim 1 wherein commutating the first shutoff current further comprises coupling the lower collector-emitter to the lower terminal.

6. The method of claim 5 wherein coupling the lower collector-emitter to the lower terminal further comprises coupling the lower collector-emitter to the lower terminal by way of a voltage source or a current source.

7. The method of claim 1 further comprising, after blocking current from the upper terminal to the lower terminal:
conducting a second load current from the lower terminal of the power module to the lower base, through the transistor, and from the upper base to the upper terminal; and then responsive to assertion of a second interrupt signal
interrupting the second load current from the upper base to the upper terminal by opening an upper-main FET and commutating a second shutoff current through an upper collector-emitter to the upper terminal; and
blocking current from the lower terminal to the upper terminal by the transistor.

8. The method of claim 7:
wherein interrupting the second load current further comprises interrupting the second load current with the upper-main FET having a breakdown voltage of 100 Volts or less; and
wherein blocking current from the lower terminal to the upper terminal further comprises blocking at an applied voltage across the lower terminal and the upper terminal of 600 Volts or greater.

9. A switch assembly comprising:
an upper terminal, a lower terminal, and an upper-control input;
a transistor defining an upper base, an upper collector-emitter, a lower base, and a lower collector-emitter;
an upper-main FET defining a first lead coupled to the upper terminal, a second lead coupled to the upper base, and a gate;
a lower-main FET defining a first lead coupled to the lower base, a second lead coupled to the lower terminal, and a gate;
a controller coupled to the upper-control input, the gate of the upper-main FET, and the gate of the lower-main FET, and for a first applied voltage across the upper terminal and lower terminal, the controller configured to:
assert the gate of the upper-main FET to make the upper-main FET conductive, arrange the transistor for conduction from the upper base to the lower base, and assert the gate of the lower-main FET to make the lower-main FET conductive such that a first load current flows from the upper terminal to the lower terminal;
sense de-assertion of the upper-control input; and responsive to de-assertion of the upper-control input
de-assert the gate of the lower-main FET to interrupt the first load current from the lower base.

10. The switch assembly of claim 9 wherein a breakdown voltage of the transistor is 600 Volts or greater, and the breakdown voltage of the lower-main FET is 100 Volts or less.

11. The switch assembly of claim 9 wherein a breakdown voltage of the transistor is about 1200 Volts, and the breakdown voltage of the lower-main FET is 80 Volts or less.

12. The switch assembly of claim 9 further comprising:
an upper-CE source and an upper-CE FET, the upper-CE source arranged to selectively inject charge carriers into the upper collector-emitter through the upper-CE FET; and
wherein when the controller arranges the transistor for conduction from the upper base to the lower base, the controller is further configured to make the upper-CE FET conductive to inject charge carriers into the upper collector-emitter; and
wherein when the controller senses de-assertion of the upper-control input, the controller is further configured to make the upper-CE FET non-conductive to cease injection of charge carriers into the upper collector-emitter.

13. The switch assembly of claim 12 wherein when the controller makes the upper-CE FET non-conductive, the controller is configured to make the upper-CE FET non-conductive a predetermined period of time that is non-zero before de-asserting the gate of the lower-main FET.

14. The switch assembly of claim 12 wherein when the controller senses de-assertion of the upper-control input, the controller is further configured to electrically float the upper collector-emitter.

15. The switch assembly of claim 9 further comprising:
a lower-CE FET defining a first lead coupled to the lower collector-emitter, a second lead coupled to the lower terminal, and a gate coupled to the controller;
wherein when the controller senses de-assertion of the upper-control input, the controller is further configured to assert the gate of the lower-CE FET to commutate a shutoff current to the lower terminal.

16. The switch assembly of claim 15 further comprising:
a lower-CE source arranged to selectively extract charge carriers from the lower collector-emitter through the lower-CE FET;
wherein when the controller senses de-assertion of the upper-control input, the controller is further configured to make the lower-CE FET conductive to extract charge carriers from the lower collector-emitter.

17. The switch assembly of claim 9 further comprising:
a lower-control input coupled to the controller; and
wherein for a second applied voltage across the upper terminal and lower terminal, the second applied voltage having a polarity opposite the first applied voltage, the controller is further configured to:
assert the gate of the lower-main FET to make the lower-main FET conductive, arrange the transistor for conduction from the lower base to the upper base, and assert the gate of the upper-main FET to make the upper-main FET conductive such that a second load current flows from the lower terminal to the upper terminal;
sense de-assertion of the lower-control input; and responsive to de-assertion of the lower-control input
de-assert the gate of the upper-main FET to interrupt the second load current from the upper base.

18. The switch assembly of claim 17 further comprising:
a lower-CE source and a lower-CE FET, the lower-CE source arranged to selectively inject charge carriers into the lower collector-emitter through the lower-CE FET; and
wherein when the controller arranges the transistor for conduction from the lower base to the upper base, the controller is further configured to make the lower-CE FET conductive to inject charge carriers into the lower collector-emitter; and
wherein when the controller senses de-assertion of the lower-control input, the controller is further configured to make the lower-CE FET non-conductive to cease injection of charge carriers into the lower collector-emitter.

19. A method of operating a bi-directional double-base bipolar junction transistor, the method comprising:
making the transistor conductive from an upper base to a lower base by supplying current to an upper collector-emitter of the transistor and electrically floating a lower collector-emitter of the transistor; and then
making the transistor non-conductive by electrically floating the upper collector-emitter, electrically floating the lower base, and conducting a shutoff current through the lower collector-emitter of the transistor.

20. The method of claim 19 wherein electrically floating the lower base further comprises making non-conductive a lower-main electrically-controlled switch having a first lead coupled to the lower base.

21. The method of claim 19 wherein making the transistor conductive further comprises:
closing an upper-main electrically-controlled switch coupled between an upper terminal and the upper base; and
closing a lower-main electrically-controlled switch coupled between a lower terminal and the lower base.

22. The method of claim 21 wherein making the transistor non-conductive further comprises:
opening the upper-main electrically-controlled switch;
conducting the shutoff current to the upper base through a diode associated with the upper-main electrically-controlled switch; and
commutating the shutoff current from the lower base to the lower collector-emitter by opening the lower-main electrically-controlled switch.
